(19) United States
(12) Patent Application Publication
(10) Pub. No.: US 2024/0274579 A1
(43) Pub. Date: Aug. 15, 2024

(54) SEMICONDUCTOR PACKAGE

(71) Applicant: Samsung Electronics Co., Ltd., Suwon-si (KR)

(72) Inventors: Choongbin Yim, Suwon-si (KR); Jongkook Kim, Suwon-si (KR)

(21) Appl. No.: 18/417,264

(22) Filed: Jan. 19, 2024

(30) Foreign Application Priority Data
Feb. 9, 2023 (KR) 10-2023-0017572

(51) Int. Cl. H01L 25/065; H01L 23/00; H01L 23/31; H01L 23/48; H01L 23/498; H01L 23/538; H01L 25/10; H10B 80/00

(52) U.S. Cl. CPC H01L 25/0657; H01L 23/3135; H01L 23/481; H01L 23/49811; H01L 23/5383; H01L 24/08; H01L 24/16; H01L 24/32; H01L 25/105; H10B 80/00; H01L 2224/08145; H01L 2224/16145; H01L 2224/16227; H01L 2224/32225

(57) ABSTRACT

A semiconductor package includes a chip structure including a first stack semiconductor chip, which includes a first sub-chip and a second sub-chip that is bonded to the first sub-chip and is of a different type from the first sub-chip, a first molding layer configured to mold the second sub-chip on the first sub-chip, and a first redistribution structure arranged above the first stack semiconductor chip and the first molding layer, a second redistribution structure arranged under the chip structure and bonded to the chip structure, a bonding wire electrically connecting the second redistribution structure to the first redistribution structure, and a second molding layer configured to seal, on the second redistribution structure, the chip structure and the bonding wire.

### CROSS-REFERENCE TO RELATED APPLICATION

This application is based on and claims priority under 35 U.S.C. § 119 to Korean Patent Application No. 10-2023-0017572, filed on Feb. 9, 2023, in the Korean Intellectual Property Office, the disclosure of which is incorporated by reference herein in its entirety.

### BACKGROUND

The inventive concept relates to a semiconductor package, and more particularly, to a semiconductor package enabling a reliable electrical connection between a stack semiconductor chip and redistribution structures.

With the rapid development in the electronics industry and the demands of users, electronic devices are miniaturized and multifunctional and have large capacities; accordingly, highly integrated stack semiconductor chips are required. In addition, a semiconductor package electrically connecting a stack semiconductor chip to redistribution structures is suggested.

### SUMMARY

Aspects of the inventive concept provide a semiconductor package that provides a reliable electrical connection between a stack semiconductor chip and redistribution structures.

According to an aspect of the inventive concept, there is provided a semiconductor package including a chip structure including a first stack semiconductor chip, which includes a first sub-chip and a second sub-chip that is bonded to the first sub-chip and is of a different type from the first sub-chip, a first molding layer configured to mold the second sub-chip on the first sub-chip, and a first redistribution structure arranged above the first stack semiconductor chip and the first molding layer, a second redistribution structure arranged under the chip structure and bonded to the chip structure, a bonding wire electrically connecting the second redistribution structure to the first redistribution structure, and a second molding layer sealing, on the second redistribution structure, the chip structure and the bonding wire.

According to another aspect of the inventive concept, there is provided a semiconductor package including a first redistribution structure including a fan-in region and fan-out regions, which surround the fan-in region, and including the first redistribution bonding pads arranged in the fan-out regions, a chip structure arranged on the first redistribution structure in the fan-in region, wherein the chip structure includes a first stack semiconductor chip including a first sub-chip and a second sub-chip that is of a different type from the first sub-chip and is bonded to the first sub-chip; a first molding layer sealing the second sub-chip on the first sub-chip, and a second redistribution structure arranged on the first stack semiconductor chip and the first molding layer, the second redistribution structure including a second redistribution bonding pad in the fan-in region, a bonding wire electrically connecting the second redistribution bonding pad in the fan-in region to a first redistribution bonding pad in one of the fan-out regions, and a second molding layer molding the chip structure and the bonding wire on the first redistribution structure in the fan-in region and the fan-out regions.

According to another aspect of the inventive concept, there is provided a semiconductor package including a first redistribution structure including a fan-in region and fan-out regions, which are located on opposite sides of the fan-in region, and including a first redistribution bonding pad in the fan-out regions, a chip structure arranged on the first redistribution structure in the fan-in region, the chip structure including a first stack semiconductor chip including a first sub-chip and a second sub-chip that is of a different type from the first sub-chip and is bonded to the first sub-chip by an internal connection terminal, a first molding layer sealing the second sub-chip on the first sub-chip, and a second redistribution structure arranged above the first stack semiconductor chip and the first molding layer, the second redistribution structure including a second redistribution bonding pad in the fan-in region, a bonding wire electrically connecting the second redistribution bonding pad in the fan-in region to the first redistribution bonding pad in the fan-out regions, and a second molding layer molding the chip structure and the bonding wire above the first redistribution structure in the fan-in region and the fan-out regions.

The first sub-chip includes a first sub-chip pad and a sub-through via, the second sub-chip includes a second sub-chip pad, the first sub-chip pad is bonded to the second sub-chip pad by the internal connection terminal, and second widths of the second redistribution structure and the first sub-chip are less than a first width of the first redistribution structure

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package according to an embodiment;

FIG. 1B is an enlarged view of a portion of the semiconductor package of FIG. 1A;

FIG. 2A is a cross-sectional view of a semiconductor package according to an embodiment;

FIG. 2B is an enlarged view of a portion of the semiconductor package of FIG. 2A;

FIG. 3 is a cross-sectional view of a chip structure included in a semiconductor package, according to an embodiment;

FIG. 4 is a cross-sectional view of a chip structure included in a semiconductor package, according to an embodiment;

FIGS. 5 to 9 are cross-sectional views for explaining a method of manufacturing the semiconductor package of FIGS. 1A and 1B;

FIGS. 10 to 12 are cross-sectional views for explaining a method of manufacturing the semiconductor package of FIGS. 2A and 2B;

FIG. 13 is a cross-sectional view of a semiconductor package according to an embodiment;

FIG. 14 is a cross-sectional view for explaining a method of manufacturing the semiconductor package of FIG. 13;

FIG. 15 is a cross-sectional view of a semiconductor package according to an embodiment;

FIG. 16 is a cross-sectional view for explaining a method of manufacturing the semiconductor package of FIG. 15;

FIG. 17 is a schematic block diagram of a structure of a semiconductor package, according to an embodiment; and

FIG. 18 is a schematic block diagram of a structure of a semiconductor package, according to an embodiment.

### DETAILED DESCRIPTION OF THE EMBODIMENTS

Hereinafter, one or more embodiments of the inventive concept are described in detail with reference to the attached drawings. Like reference numerals in the drawings denote like elements, and repeated descriptions thereof will be omitted.

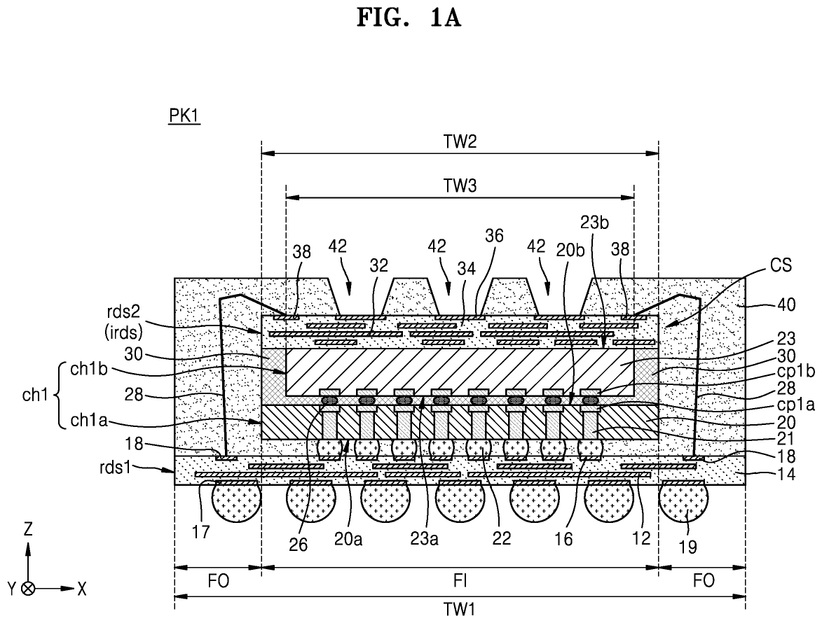

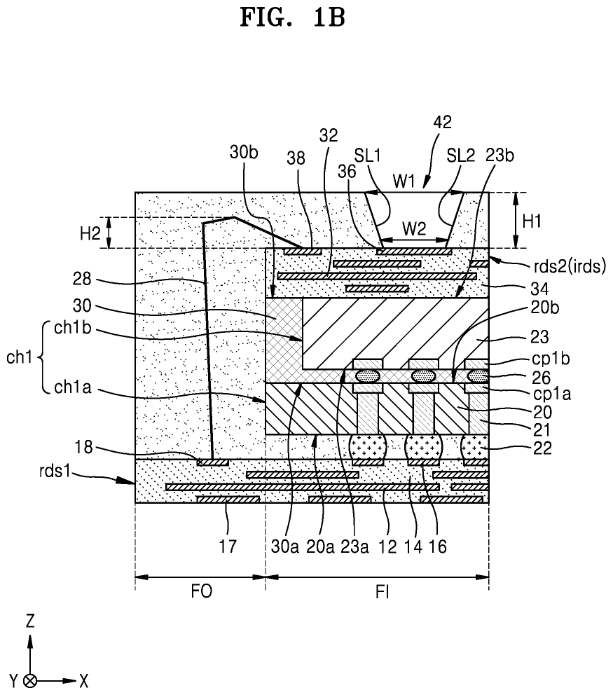

FIG. 1A is a cross-sectional view of a semiconductor package according to an embodiment, and FIG. 1B is an enlarged view of a portion of the semiconductor package of FIG. 1A.

Referring to FIG. 1A, a semiconductor package PK1 may include a first redistribution structure rds1, a chip structure CS, a bonding wire 28, and a second molding layer 40. The chip structure CS may include a first stack semiconductor chip ch1, a second redistribution structure rds2, and a first molding layer 30. In the following drawings, the X and Y directions refer to the horizontal directions relative to (e.g., parallel to) the surface (e.g., a top/bottom surface) of the first redistribution structure rds1, and the Z direction refers to a direction perpendicular to the surface (e.g., the top/bottom surface) of the first redistribution structure rds1. For example, the X direction may be a first horizontal direction, the Y direction may be a second horizontal direction, and the Z direction may be a vertical direction.

Spatially relative terms, such as “beneath,” “below,” “lower,” “above,” “upper,” “horizontal,” “vertical” and the like, may be used herein for ease of description to describe positional relationships, such as illustrated in the figures. It will be understood that the spatially relative terms encompass different orientations of the device in addition to the orientation depicted in the figures.

The semiconductor package PK1 may include the first redistribution structure rds1 extending to the outside (or the perimeter) of the first semiconductor chip ch1, e.g., in a plan view. Accordingly, the semiconductor package PK1 may be a fan-out package. In addition, the semiconductor package PK1 may be a wafer level package in which package manufacture is performed at a wafer level. Collectively, the semiconductor package PK1 may be a Fan Out Wafer Level Package (FOWLP). Hereinafter, the structure of the semiconductor package PK1 is described in detail.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first redistribution structure rds1 may include a fan-in region FI and fan-out regions FO. The fan-in region FI may be a region in which the chip structure CS, e.g., the first stack semiconductor chip ch1, is mounted. For example, the fan-in region is a region of the first redistribution structure rds1 vertically overlapping the chip structure CS, and the fan-out region is a region of the first redistribution structure rds1 not vertically overlapping the chip structure CS. The fan-out regions FO may be located on both sides of the fan-in region FI, e.g., in a cross-sectional view. The fan-out regions FO may surround the fan-in region FI in a plan view. The fan-out region FO may be a region in which the molding layer 40 is formed.

The first redistribution structure rds1 may include a first redistribution layer 12 and a first redistribution insulating layer 14. The first redistribution structure rds1 may have a first width TW1, e.g., in the first horizontal direction X. The first width TW1 of the first redistribution structure rds1 may be several tens of millimeters (mm) to several hundred mm. The first redistribution layer 12 may be formed inside the first redistribution insulating layer 14. The first redistribution layer 12 may be insulated by the first redistribution insulating layer 14.

The first redistribution layer 12 may be a conductor pattern and a plurality of first redistribution layers 12 may be formed in the first redistribution insulating layer 14. The first redistribution layer 12 may include a metal layer including or formed of a material, such as copper, nickel, stainless steel, or beryllium copper. The first redistribution insulating layer 14 may include or be formed of an insulating polymer or a silicon-containing insulating material. The insulating polymer may include or may be, for example, photosensitive polyimide (PSPI), polybenzoxazole (PBO), a phenolic polymer, and/or a benzocyclobutene-based polymer (BCB). The silicon-containing insulating material may include or may be silicon oxide, silicon nitride, silicon oxynitride, and/or tetraethyl orthosilicate (TEOS).

The first redistribution structure rds1 may include first connection pads 16, second connection pads 17, and first redistribution bonding pads 18. The first connection pads 16 may be arranged above the first redistribution structure rds1. For example, the first connection pads 16 may be formed in the top surface of the first redistribution structure rds1. The first connection pads 16 may be located in the fan-in region FI. Each first connection pad 16 may be a portion of the first redistribution layer 12.

Each first connection pad 16 may be electrically connected to the first stack semiconductor chip ch1 through a first chip connection terminal 22. A plurality of first chip connection terminals 22 may be provided in the semiconductor package PK1. The first chip connection terminal 22 may include or may be at least any one of a solder, a bump, and a pillar.

As used herein, components described as being “electrically connected” are configured such that an electrical signal can be transferred from one component to the other (although such electrical signal may be attenuated in strength as it transferred and may be selectively transferred).

The second connection pads 17 may be arranged under the first redistribution structure rds1. For example, the second connection pads 17 may be formed in the bottom surface of the first redistribution structure rds1. The second connection pads 17 may be located in the fan-in region FI and in the fan-out regions FO. Each second connection pad 17 may be a portion of the first redistribution layer 12. The second connection pad 17 may be electrically connected to a first external connection terminal 19. A plurality of first external connection terminals 19 may be provided in the semiconductor package PK1. The first external connection terminal 19 may include or may be at least any one of a solder, a bump, and a pillar.

The first redistribution bonding pads 18 may be arranged above the first redistribution structure rds1. For example, the first redistribution bonding pads 18 may be formed in the top surface of the first redistribution structure rds1. The first redistribution bonding pads 18 may be located in the fan-out region FO. The first redistribution bonding pads 18 may be formed in all of the fan-out regions FO located on both sides of the fan-in region FI. Each first redistribution bonding pad 18 may be a portion of the first redistribution layer 12. The first redistribution bonding pad 18 may be a pad to which the bonding wire 28 is bonded.

The chip structure CS may be arranged above the first redistribution structure rds1. The chip structure CS may be bonded to the first redistribution structure rds1. The chip structure CS may include the first stack semiconductor chip ch1, the second redistribution structure rds2, and the first molding layer 30. The first stack semiconductor chip ch1 may be arranged above the first redistribution structure rds1. In some embodiments, the first stack semiconductor chip ch1 may include or may be any one of a controller chip 1020 and a power management integrated chip (PMIC) 1022.

The first stack semiconductor chip ch1 may include a first sub-chip ch1a and a second sub-chip ch1b bonded to the first sub-chip ch1a. The first sub-chip ch1a may be of a different type from the second sub-chip ch1b.

In some embodiments, the first sub-chip ch1a may be a cache memory chip, and the second sub-chip ch1b may be a PMIC or a logic chip. The logic chip may be a controller chip, a central processing unit (CPU) chip, a graphics processing unit (GPU) chip, or an application processor (AP) chip. Because the chip structure CS may include various chips, the semiconductor package PK1 may realize a system-in-package.

The first chip connection terminals 22 may be formed under (e.g., contact) the first sub-chip ch1a forming the first stack semiconductor chip ch1. The first sub-chip ch1a may be electrically connected to the first connection pads 16 of the first redistribution structure rds1 through the first chip connection terminals 22.

It will be understood that when an element is referred to as being “connected,” “bonded” or “coupled” to or “on” another element, it can be directly connected, bonded or coupled to or on the other element or intervening elements may be present. In contrast, when an element is referred to as being “directly connected,” “directly bonded” or “directly coupled” to another element, or as “contacting” or “in contact with” another element, there are no intervening elements present at the point of contact.

The first sub-chip ch1a and the second sub-chip ch1b may respectively include a first semiconductor substrate 20 and a second semiconductor substrate 23. Each of the first semiconductor substrate 20 and the second semiconductor substrate 23 may include a semiconductor element, such as germanium (Ge), a compound semiconductor, such as silicon carbide (SiC), gallium arsenide (GaAs), indium arsenide (InAs), or indium phosphide (InP), or glass. In certain embodiments, the first semiconductor substrate 20 and the second semiconductor substrate 23 may each have a silicon on insulator (SOI) structure.

The first semiconductor substrate 20 and the second semiconductor substrate 23 may each include a conductive region, for example, a well doped with impurities. The first semiconductor substrate 20 and the second semiconductor substrate 23 may each have a device isolation structure, such as a shallow trench isolation (STI) structure.

The first semiconductor substrate 20 may have a first lower surface (e.g., a bottom surface) 20a and a first upper surface (e.g., a top surface) 20b. The second semiconductor substrate 23 may have a second lower surface (e.g., a bottom surface) 23a and a second upper surface (e.g., a top surface) 23b. The first upper surface 20b and the second lower surface 23a may each be an active surface on which active devices are formed. The first lower surface 20a and the second upper surface 23b may each be an inactive surface on which no active devices are formed.

On the first upper surface 20b and the second lower surface 23a, various types of individual devices (not shown) may be formed. The individual devices may include various microelectronic devices, for example, a metal-oxide-semiconductor field effect transistor (MOSFET) such as a complementary metal-insulator-semiconductor (CMOS) transistor, an image sensor such as system large scale integration (LSI) or a CMOS imaging sensor (CIS), a micro-electro-mechanical system (MEMS), active elements, passive elements, and the like.

On the first upper surface 20b of the first semiconductor substrate 20 forming the first sub-chip ch1a, first sub-chip pads cp1a may be arranged. Sub-through vias 21 may be formed in the first semiconductor substrate 20, the sub-through vias 21 being electrically connected to the first sub-chip pads cp1a. The sub-through vias 21 may penetrate between the first upper surface 20b and the first lower surface 20a of the first semiconductor substrate 20.

Second sub-chip pads cp1b may be arranged on the second lower surface 23b of the second semiconductor substrate 23 forming (e.g., included in) the second sub-chip ch1b. For example, the second sub-chip pads cp1b may be formed at the bottom surface of the second semiconductor substrate 23. The first sub-chip pads cp1a and the second sub-chip pads cp1b may be bonded (e.g., electrically connected) to each other through internal connection terminals 26. The first sub-chip pads cp1a and the second sub-chip pads cp1b may be electrically connected to each other through the internal connection terminals 26. The second sub-chip ch1b may be electrically connected to the first redistribution structure rds1 through the internal connection terminals 26, the sub-through vias 21, and the first chip connection terminals 22. The second sub-chip ch1b may have a third width TW3, e.g., in the first horizontal direction X. The third width TW3 of the second sub-chip ch1b may be less than the first width TW1 of the first redistribution structure rds1. The third width TW3 of the second sub-chip ch1b may be tens of mm to several hundred mm.

In the present embodiment, it is described that the first sub-chip ch1a and the second sub-chip ch1b bond between the active surfaces, but in some embodiments, the first sub-chip ch1a and the second sub-chip ch1b may bond the inactive surfaces to each other or bond the active surface and the inactive surface to each other.

The first molding layer 30 may be formed to seal the second sub-chip ch1b on the first sub-chip ch1a. The first molding layer 30 may be located on both sidewalls of the second sub-chip ch1b and between the first sub-chip ch1a and the second sub-chip ch1b. For example, the first molding layer 30 may contact sidewalls of the second sub-chip ch1b, the top surface of the first sub-chip ch1a, and the bottom surface of the second sub-chip ch1b.

As shown in FIG. 1B, the first molding layer 30 may include a lower surface (e.g., a bottom surface) 30a and an upper surface (e.g., a top surface) 30b. The lower surface 30a of the first molding layer 30 may be in the same plane as (e.g., contact) the first upper surface 20b of the first semiconductor substrate 20. The upper surface 30b of the first molding layer 30 may be in the same plane as (e.g., be coplanar with) the second upper surface 23b of the second semiconductor substrate 23. The first molding layer 30 may include or be formed of an insulating polymer. In some embodiments, the first molding layer 30 may include or be formed of an Epoxy Molding Compound (EMC).

The second redistribution structure rds2 may be arranged on (e.g., may contact) the upper surface of the second sub-chip ch1b and the upper surface 30b of the first molding layer 30. The second redistribution structure rds2 may be an interposer redistribution structure irds. As described below, an upper semiconductor package may be mounted on the second redistribution structure rds2.

The second redistribution structure rds2 may be arranged in the fan-in region FI. The second redistribution structure rds2 may include a second redistribution layer 32 and a second redistribution insulating layer 34. The second redistribution structure rds2 may have a second width TW2, e.g., in the first horizontal direction X. The second width TW2 may be the width of the first sub-chip ch1a, e.g., in the first horizontal direction X. For example, the second redistribution structure rds2 and the first sub-chip ch1a may have the same width, e.g., in the first horizontal direction X and/or in the second horizontal direction Y.

The second width TW2 of the second redistribution structure rds2 may be less than the first width TW1 of the first redistribution structure rds1. The second width TW2 of the second redistribution structure rds2 may be tens of mm to several hundred mm.

In the present embodiment, it is illustrated that the second width TW2 of the second redistribution structure rds2 is greater than the third width TW3 of the second sub-chip ch1b, but the second width TW2 of the second redistribution structure rds2 may be the same as or less than the third width TW3 of the second sub-chip ch1b in certain embodiments.

The second redistribution layer 32 may be formed inside the second redistribution insulating layer 34. The second redistribution layer 32 may be insulated by the second redistribution insulating layer 34. The second redistribution layer 32 may be a conductor pattern and a plurality of second redistribution layers 32 may be formed in the second redistribution insulating layer 34. The second redistribution layer 32 may include or be formed of a metal layer including a material, such as copper, nickel, stainless steel, or beryllium copper. The second redistribution insulating layer 34 may include or be formed of an insulating polymer or a silicon-containing insulating material.

The second redistribution structure rds2 may include third connection pads 36 and second redistribution bonding pads 38. The third connection pads 36 may be arranged on the second redistribution structure rds2. For example, the third connection pads 36 may be formed at a top surface of the second redistribution structure rds2. The third connection pads 36 may be located in the fan-in region FI. The third connection pads 36 may be a portion of the second redistribution layer 32. As described below, the third connection pads 36 may be exposed by first connection holes 42 formed in the second molding layer 40.

The second redistribution bonding pads 38 may be arranged on the second redistribution structure rds2. For example, the second redistribution bonding pads 38 may be formed at the top surface of the second redistribution structure rds2. The second redistribution bonding pads 38 may be located in the fan-in region FI. The second redistribution bonding pads 38 may be formed on both sides (e.g., in opposite side areas) of the fan-in region FI. Each second redistribution bonding pad 38 may be a portion of the second redistribution layer 32. The second redistribution bonding pad 38 may be a pad to which the bonding wire 28 is bonded (e.g., contacts and/or is electrically connected).

The bonding wire 28 may electrically connect the second redistribution bonding pad 38 to the first redistribution bonding pad 18. The bonding wire 28 may electrically connect the second redistribution structure rds2 to the first redistribution structure rds1. The bonding wire 28 may be a metal wire, for example, a gold wire or a copper wire.

The bonding wire 28 may have a second height H2 on the surface of the second redistribution structure rds2. The second height H2 of the bonding wire 28 may be in a range from several tens of micrometers (um) to several hundred um. In some embodiments, the second height H2 of the bonding wire 28 may be in a range from about 10 um to about 100 um. For example, the bonding wire 28 may extend above the top surface of the second redistribution structure rds2, and a height H2 from the top surface of the second redistribution structure rds2 to the highest point of the bonding wire 28 in the vertical direction Z may be between 10 um and 100 um.

In this regard, when the second redistribution structure rds2 is electrically connected to the first redistribution structure rds1 by a metal pillar (or a metal post), the height of the metal pillar is as high as hundreds of um. Because the plating process needs to be performed a number of times to form the metal pillar of several hundred um, the processing time may be too long, and the defect occurrence rate may be high.

On the contrary, when the second redistribution structure rds2 is electrically connected to the first redistribution structure rds1 by the bonding wire 28, the second redistribution structure rds2 is electrically reliably connected to the first redistribution structure rds1. In addition, although pitches of the first redistribution bonding pad 18 and the second redistribution bonding pad 38 are reduced, the first redistribution bonding pad 18 and the second redistribution bonding pad 38 may be easily connected to each other by the bonding wire 28.

The second molding layer 40 may mold the first stack semiconductor chip ch1, the second redistribution structure rds2, the bonding wire 28, and the first molding layer 30 on the first redistribution structure rds1. The second molding layer 40 may include or be formed of an insulating polymer. The second molding layer 40 may include or be formed of the same material as the first molding layer 30. In some embodiments, the second molding layer 40 may include or be formed of an EMC. The first molding layer 30 and the second molding layer 40 may form the molding layers 30 and 40.

In the second molding layer 40 on the second redistribution structure rds2, a first connection hole 42 exposing a third connection pad 36 may be arranged/formed. A plurality of first connection holes 42 exposing the third connection pads 36 may be provided in the second molding layer 40. As shown in FIG. 1B, a first height (or a thickness, H1) of the second molding layer 40 on the second redistribution structure rds2 may be in a range from several tens of um to several hundred um. For example, the first height H1 may be a distance from the top surface of the second redistribution structure rds2 to a top surface of the second molding layer 40 in the vertical direction Z.

In some embodiments, the first height (or the thickness, H1) of the second molding layer 40 on the second redistribution structure rds2 may be in a range from about 20 um to about 500 um. The first connection hole 42 may be formed by removing a portion of the second molding layer 40, which is formed on the second redistribution structure rds2, e.g., by a laser drilling method.

Each first connection hole 42 may expose a corresponding one of the third connection pads 36. The first connection hole 42 may have an upper width W1 and a lower width W2, e.g., in the first horizontal direction X as shown in FIG. 1B. The upper width W1 of the first connection hole 42 may be greater than the lower width W2 thereof. The upper width W1 and the lower width W2 of the first connection hole 42 may be in a range from several tens of um to several hundred um. In some embodiments, the upper width W1 and the lower width W2 of the first connection hole 42 may be in a range from about 50 um to about 500 um.

Both sidewalls SL1 and SL2 (e.g., opposite sidewalls) of the first connection hole 42 may be inclined. The absolute values of the inclinations of the sidewalls SL1 and SL2 of the first connection hole 42 may be the same as each other. As described below, the third connection pads 36 exposed by the first connection holes 42 may be electrically connected to an upper semiconductor package through second external connection terminals.

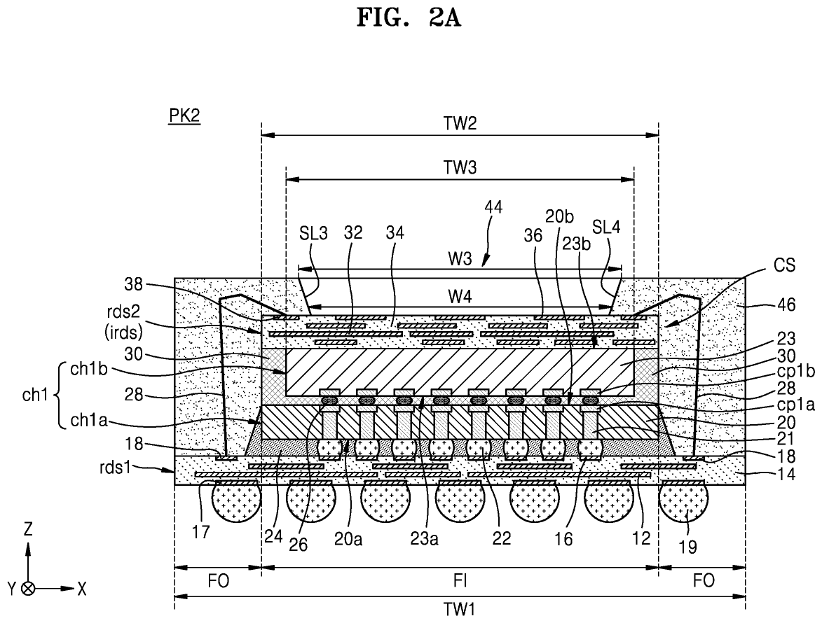

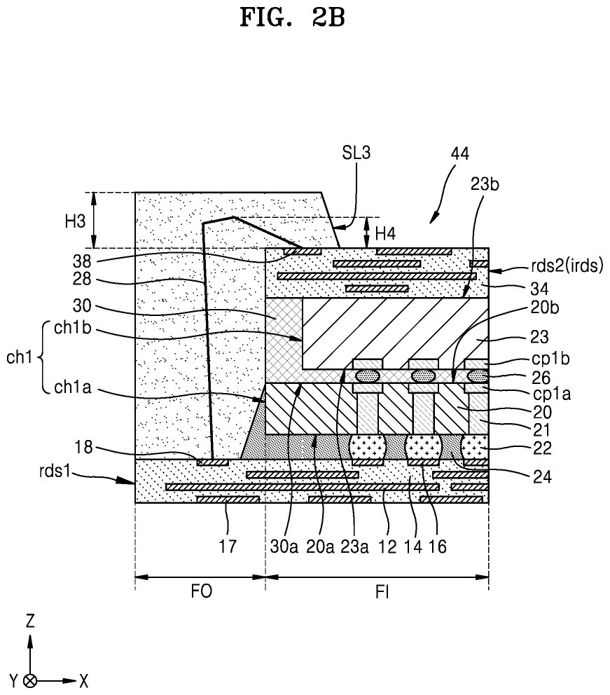

FIG. 2A is a cross-sectional view of a semiconductor package according to an embodiment, and FIG. 2B is an enlarged view of a portion of the semiconductor package of FIG. 2A.

For example, compared to the semiconductor package PK1 of FIGS. 1A and 1B, an underfill layer 24 is further formed under the first semiconductor chip ch1 in a semiconductor package PK2. The underfill layer 24 may include or be formed of an insulating polymer. Compared to the semiconductor package PK1 of FIGS. 1A and 1B, the semiconductor package PK2 includes, in the second redistribution structure rds2, a second connection hole 44 exposing the third connection pads 36.

The semiconductor package PK2 may be the same as the semiconductor package PK1 except for including the underfill layer 24 and differences between structures of the first connection holes 42 and the second connection hole 44. Therefore, descriptions provided with reference to FIGS. 1A and 1B are briefly repeated or omitted below with respect to FIGS. 2A and 2B.

The semiconductor package PK2 may include the first redistribution structure rds1, the chip structure CS, the underfill layer 24, the second redistribution structure rds2, the bonding wire 28, a second molding layer 46, and the second connection hole 44. The chip structure CS may include the first stack semiconductor chip ch1, the second redistribution structure rds2, and the first molding layer 30.

The first stack semiconductor chip ch1 may include the first sub-chip ch1a and the second sub-chip ch1b bonded to the first sub-chip ch1a. The first molding layer 30 may be located on both sidewalls of the second sub-chip ch1b and between the first sub-chip ch1a and the second sub-chip ch1b. The first molding layer 30 may correspond to (e.g., the same as) the first molding layer 30 of FIGS. 1A and 1B.

The second molding layer 46 may encapsulate (or seal) the chip structure CS, the bonding wire 28, and the underfill layer 24 on the first redistribution structure rds1. The second molding layer 46 may correspond to (e.g., a replacement of) the second molding layer 40 of FIGS. 1A and 1B.

The first molding layer 30 and the second molding layer 46 may each include or be formed of, for example, an EMC. On the first redistribution structure rds1, the underfill layer 24 may be arranged under the first sub-chip ch1a. The underfill layer 24 may contact and support first chip connection terminals 22 on the first redistribution structure rds1.

The bonding wire 28 may electrically connect the second redistribution bonding pad 38 to the first redistribution bonding pad 18. As shown in FIG. 2B, the bonding wire 28 may have a fourth height H4 on the surface of the second redistribution structure rds2. For example, the fourth height H4 may be a distance from a top surface of the second redistribution structure rds2 to a top of the bonding wire 28 in the vertical direction. The fourth height H4 of the bonding wire 28 may be in a range from several tens of um to several hundred um. In some embodiments, the fourth height H4 of the bonding wire 28 may be in a range from about 10 um to about 100 um.

In the second molding layer 46 on the second redistribution structure rds2, the second connection hole 44 exposing the third connection pads 36 may be arranged. For example, only one second connection hole 44 may be formed in the second molding layer 46. As shown in FIG. 2B, a third height (or a thickness, H3) of the second molding layer 46 on the second redistribution structure rds2 may be in a range from several tens of um to several hundred um. For example, the third height H3 may be a distance from the top surface of the second redistribution structure rds2 to a top of the second molding layer 46 in the vertical direction.

In some embodiments, the third height (or the thickness, H3) of the second molding layer 46 on the second redistribution structure rds2 may be in a range from about 20 um to about 500 um. The second connection hole 44 may be formed by forming only a portion of the second molding layer 46 on the second redistribution structure rds2. For example, the second redistribution structure rds2 may overlap the whole area of the second connection hole 44 in the vertical direction Z.

The second connection hole 44 may expose the third connection pads 36. The second connection hole 44 may have an upper width W3 and a lower width W4, e.g., in the first horizontal direction X. The upper width W3 of the second connection hole 44 may be greater than the lower width W4 thereof. The upper width W3 and the lower width W4 of the second connection hole 44 may be in a range from several tens of mm to several hundred mm.

Both sidewalls SL3 and SL4 (e.g., opposite sidewalls) of the second connection hole 44 may be inclined. The absolute values of the inclinations of the sidewalls SL3 and SL4 of the second connection hole 44 may be the same as each other. The third connection pads 36 exposed by the second connection hole 44 may be electrically connected to the upper semiconductor package through the second external connection terminal, as described below.

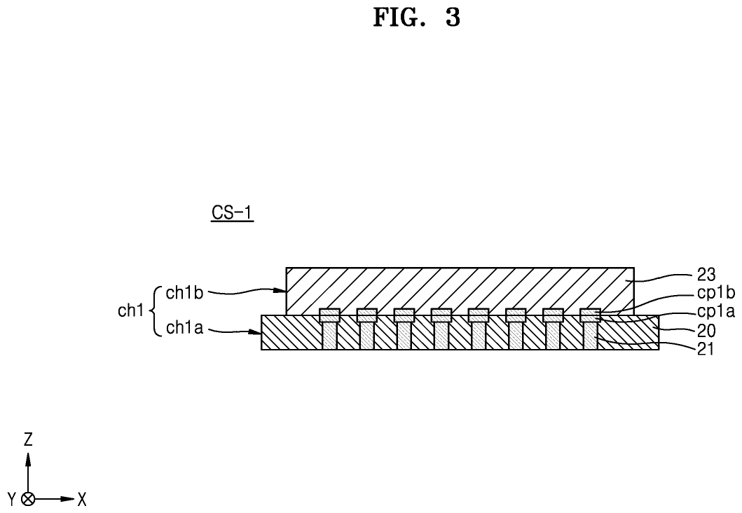

FIG. 3 is a cross-sectional view of a chip structure included in a semiconductor package, according to an embodiment.

A chip structure CS-1 may be applied, e.g., to a semiconductor package, instead of the chip structure CS of the semiconductor packages PK1 and PK2 of FIGS. 1A to 2B. The chip structure CS-1 may be the same as the chip structure CS except that the first sub-chip pad cp1a is directly bonded to (e.g., contact) the second sub-chip pad cp1b. The descriptions regarding the chip structure CS-1 of FIG. 3, which are the same as the descriptions regarding the chip structure CS of FIGS. 1A to 2B, are briefly repeated or omitted.

The chip structure CS-1 may include the first stack semiconductor chip ch1. The first stack semiconductor chip ch1 may include a first sub-chip ch1a and a second sub-chip ch1b bonded to the first sub-chip ch1a. The first sub-chip ch1a and the second sub-chip ch1b may respectively include a first semiconductor substrate 20 and a second semiconductor substrate 23.

On the surface of the first semiconductor substrate 20 forming the first sub-chip ch1a, the first sub-chip pads cp1a may be arranged/formed. The sub-through vias 21 may be formed in the first semiconductor substrate 20, the sub-through vias 21 being electrically connected to the first sub-chip pads cp1a. The sub-through vias 21 may be formed by penetrating between the upper surface and the lower surface of the first semiconductor substrate 20.

On the surface of the second semiconductor substrate 23 forming the second sub-chip ch1b, the second sub-chip pads cp1b may be arranged/formed. The first sub-chip pads cp1a may be directly bonded to (e.g., contact) the second sub-chip pads cp1b.

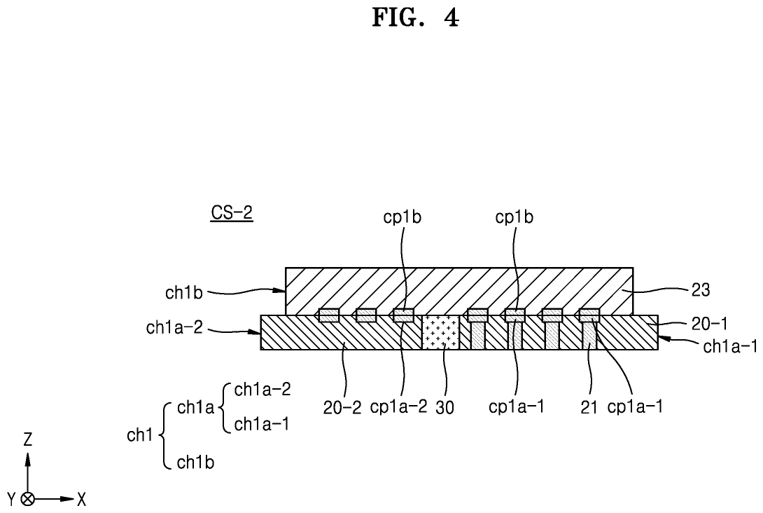

FIG. 4 is a cross-sectional view of a chip structure included in a semiconductor package, according to an embodiment.

For example, a chip structure CS-2 may be applied, e.g., to a semiconductor package, instead of the chip structure CS of the semiconductor packages PK1 and PK2 of FIGS. 1A to 2B. The chip structure CS-2 may be the same as the chip structure CS except that the first sub-chip ch1a includes a first lower sub-chip ch1a-1 and a second lower sub-chip ch1a-2 which are spaced apart from each other and that the first and second lower sub-chip pads cp1a-1 and cp1a-2 are directly bonded to (e.g., contact) the second sub-chip pads cp1b. The descriptions regarding the chip structure CS-2 of FIG. 4, which are the same as the descriptions regarding the chip structure CS of FIGS. 1A to 2B, are briefly repeated or omitted.

The chip structure CS-2 may include the first stack semiconductor chip ch1. The first stack semiconductor chip ch1 may include the first sub-chip ch1a and the second sub-chip ch1b bonded to the first sub-chip ch1a. The first sub-chip ch1a may include the first lower sub-chip ch1a-1 and the second lower sub-chip ch1a-2 which are spaced apart from each other, e.g., in a horizontal direction. A portion between the first lower sub-chip ch1a-1 and the second lower sub-chip ch1a-2 may be molded by the first molding layer 30.

The first lower sub-chip ch1a-1 and the second lower sub-chip ch1a-2 may include a first lower semiconductor substrate 20-1 and a second lower semiconductor substrate 20-2 respectively. The second sub-chip ch1b may include the second semiconductor substrate 23.

On the surface of the first lower semiconductor substrate 20-1 forming the first lower sub-chip ch1a-1, the first lower sub-chip pads cp1a-1 may be arranged/formed. The sub-through vias 21 may be formed in the first lower semiconductor substrate 20-1, the sub-through vias 21 being electrically connected to the first lower sub-chip pads cp1a-1. The sub-through vias 21 may be formed by penetrating between the upper surface and the lower surface of the first semiconductor substrate 20.

On the surface of the second lower semiconductor substrate 20-2 forming the second lower sub-chip ch1a-2, the second lower sub-chip pads cp1a-2 may be arranged/formed. No sub-through vias may be formed in the second lower semiconductor substrate 20-2. The first lower sub-chip pads cp1a-1 and the second lower sub-chip pads cp1a-2 may be collectively referred to as the first sub-chip pads.

On the surface of the second semiconductor substrate 23 forming the second sub-chip ch1b, the second sub-chip pads cp1b may be arranged/formed. The first lower sub-chip pads cp1a-1 and the second lower sub-chip pads cp1a-2 may be directly bonded to (e.g., contact) the second sub-chip pads cp1b.

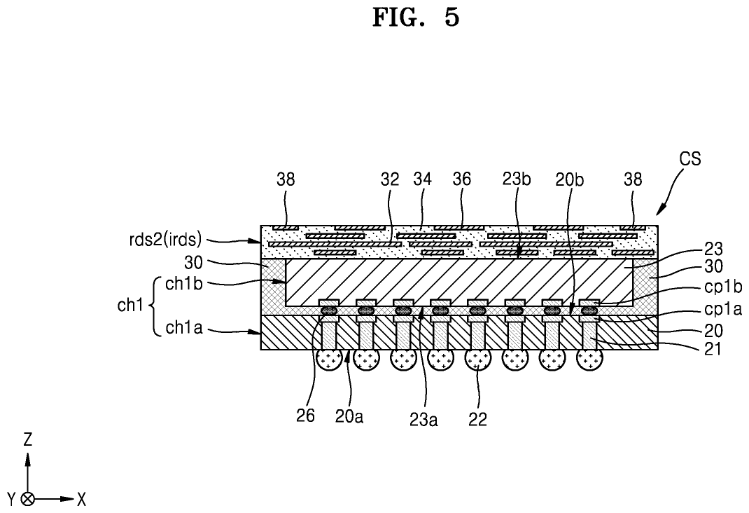

FIGS. 5 to 9 are cross-sectional views for explaining a method of manufacturing the semiconductor package of FIGS. 1A and 1B.

FIGS. 5 to 9 are provided to explain the method of manufacturing the semiconductor package PK1 of FIGS. 1A and 1B. The descriptions provided with reference to FIGS. 1A and 1B are briefly repeated or omitted in the descriptions below with respect to FIGS. 5 to 9.

FIG. 5 shows the formation of the chip structure CS. The first stack chip ch1 is formed by flip-chip bonding the second sub-chip ch1b onto the first sub-chip ch1a by using the internal connection terminals 26.

The first sub-chip ch1a may include the first semiconductor substrate 20. The first semiconductor substrate 20 may have the first lower surface 20a and the first upper surface 20b. The first lower surface 20a may be an inactive surface, and the first upper surface 20b may be an active surface.

The second sub-chip ch1b may include the second semiconductor substrate 23. The second semiconductor substrate 23 may have the second lower surface 23a and the second upper surface 23b. The second lower surface 23a may be an active surface, and the second upper surface 23b may be an inactive surface. The first sub-chip ch1a and the second sub-chip ch1b may bond between the active surfaces.

The first sub-chip pads cp1a of the first sub-chip ch1a may be electrically connected to the second sub-chip pads cp1b of the second sub-chip ch1b by the internal connection terminals 26. The first sub-chip ch1a may be electrically connected to the internal connection terminals 26 through the sub-through vias 21. For example, first sub-chip pads cp1a of the first sub-chip ch1a may contact the internal connection terminals 26 from below and the second sub-chip pads cp1b of the second sub-chip ch1b to contact the internal connection terminals 26 from above.

On the first sub-chip ch1a, the first molding layer 30 sealing the second sub-chip ch1b is formed. Next, the second redistribution structure rds2 is formed on the second sub-chip ch1b and the first molding layer 30. The second redistribution structure rds2 may be an interposer redistribution structure irds. The second redistribution structure rds2 may include the second redistribution layers 32, the second redistribution insulating layer 34, the third connection pads 36, and the second redistribution bonding pads 38. Through the above processes, the chip structure CS including the first stack semiconductor chip ch1, the second redistribution structure rds2, and the first molding layer 30 may be formed.

The first chip connection terminals 22 are formed under the first sub-chip ch1a. Each first chip connection terminal 22 may include or may be any one of a solder, a bump, and a pillar.

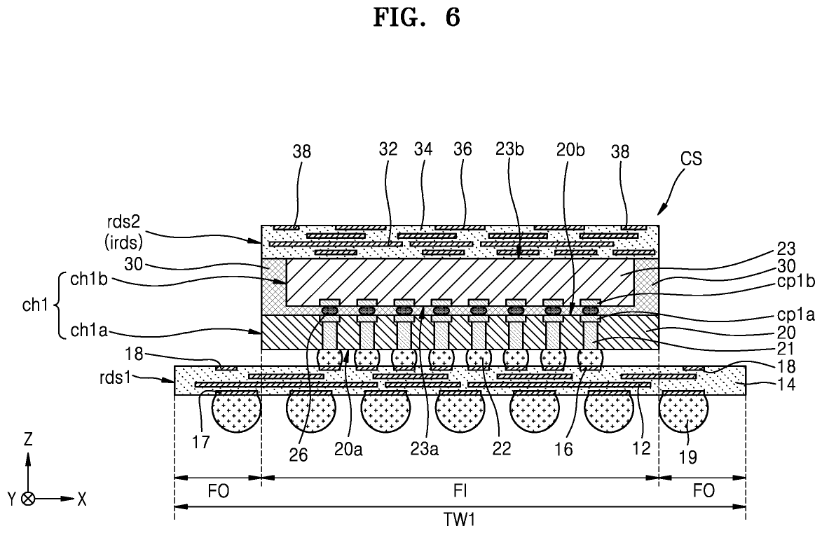

Referring to FIG. 6, the first redistribution structure rds1 including the fan-in region FI and the fan-out regions FO is prepared. The first redistribution structure rds1 may be formed by forming the first redistribution structure rds1 on a carrier substrate and then removing the carrier substrate.

The first redistribution structure rds1 may include the first redistribution layer 12, the first redistribution insulating layer 14, the first connection pads 16, the second connection pads 17, and the first redistribution bonding pads 18.

The chip structure CS is mounted on the first redistribution structure rds1 by using the first chip connection terminals 22. As the first chip connection terminals 22 are mounted on (e.g., contact) the first connection pad 16, the first redistribution structure rds1 is electrically connected to the first stack semiconductor chip ch1.

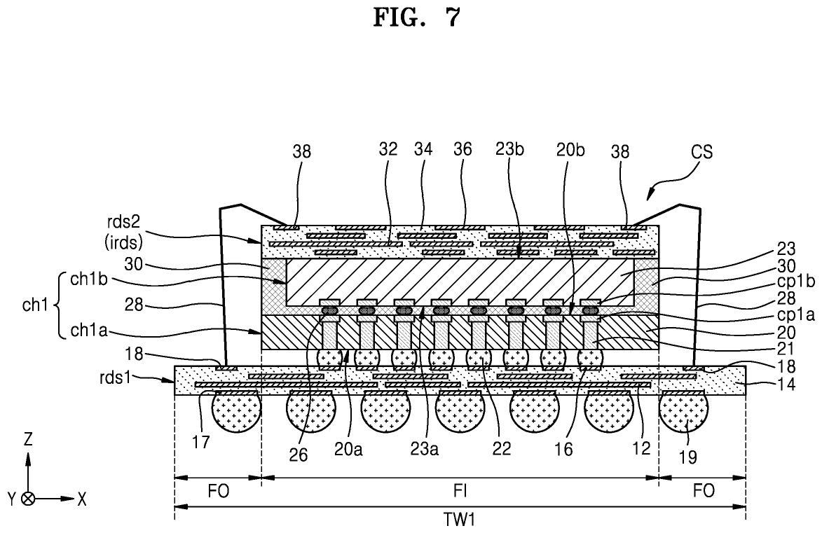

Referring to FIG. 7, the second redistribution bonding pad 38 of the second redistribution structure rds2 is electrically connected to the first redistribution bonding pad 18 of the first redistribution structure rds1 by the bonding wire 28.

As described above, the second redistribution structure rds2 is electrically connected to the first redistribution structure rds1 by the bonding wire 28 instead of a metal pillar (or a metal post), e.g., formed by an electroplating process. Accordingly, the electrical connection between the second redistribution structure rds2 and the first redistribution structure rds1 may be reliably enabled.

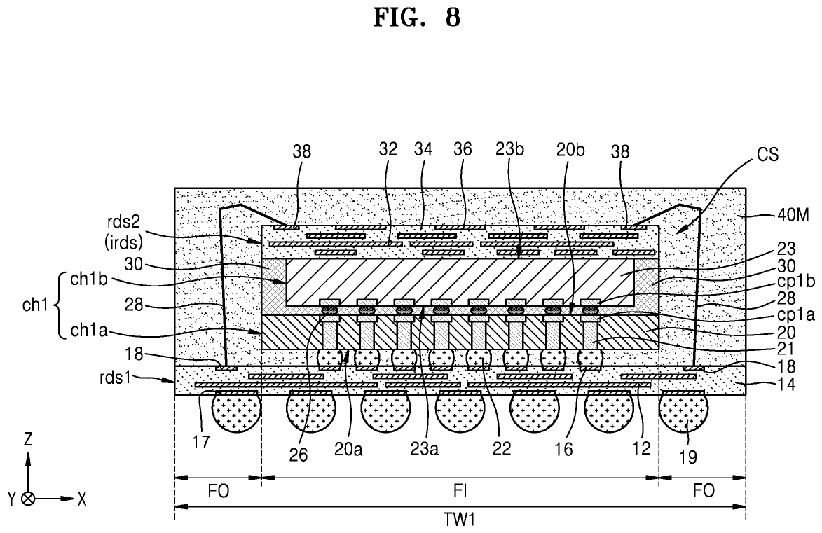

Referring to FIG. 8, on the first redistribution structure rds1, the chip structure CS, the bonding wire 28, and the first molding layer 30 are molded by a second molding material layer 40M. The second molding material layer 40M may be formed between the first chip connection terminals 22, on side portions (e.g., on side surfaces) of the first sub-semiconductor chip ch1a and the first molding layer 30, and on side and top surfaces of the second redistribution structure rds2.

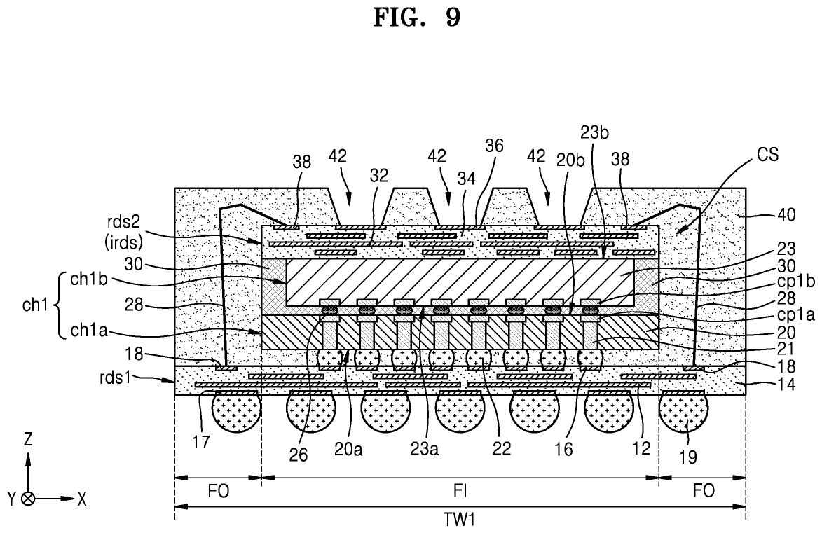

Referring to FIG. 9, the first connection holes 42 are formed in the second molding material layer (40M of FIG. 8) on the second redistribution structure rds2, the first connection holes 42 exposing the third connection pads 36. The first connection holes 42 are formed by removing portions of the second molding material layer (40M of FIG. 8) which is formed on the second redistribution structure rds2, e.g., by a laser drilling method.

Accordingly, the second molding material layer (40M of FIG. 8) may become (turn into) the second molding layer 40 having first connection holes 42. Because the shape of the first connection hole 42 is described with reference to FIG. 1B, the description is not repeated hereinafter. The semiconductor package PK1 of FIGS. 1A and 1B may be manufactured through the manufacturing processes described above.

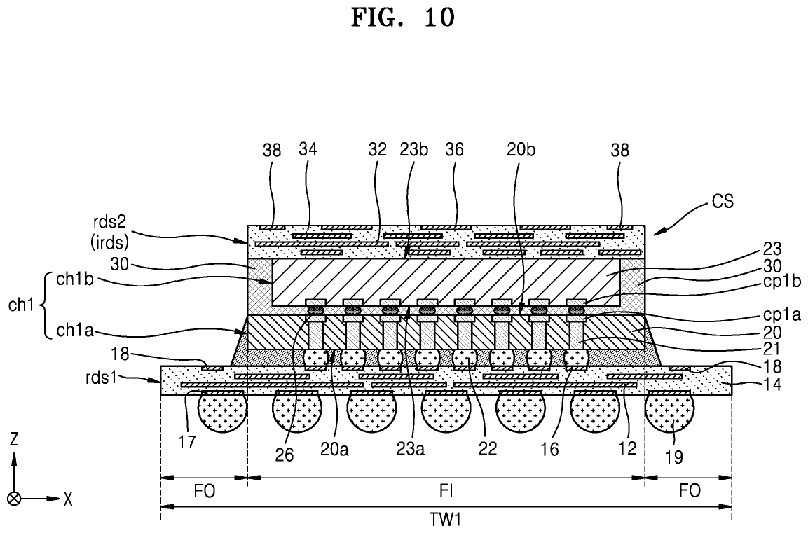

FIGS. 10 to 12 are cross-sectional views for explaining a method of manufacturing the semiconductor package of FIGS. 2A and 2B.

For example, FIGS. 10 to 12 are provided to explain the method of manufacturing a semiconductor package PK2 of FIGS. 2A and 2B. The descriptions provided with reference to FIGS. 2A and 2B above are briefly repeated or omitted below in descriptions with respect to FIGS. 10 to 12.

First of all, the same manufacturing processes as the ones of FIGS. 5 and 6 are performed in manufacturing the semiconductor package PK2. In this case, the chip structure CS is mounted on the first redistribution structure rds1 by using the first chip connection terminals 22.

Referring to FIG. 10, on the first redistribution structure rds1, the underfill layer 24 is formed on a lower portion of side surfaces and a bottom surface of the first sub-semiconductor chip ch1a and between the first chip connection terminals 22. The underfill layer 24 may contact and support the first chip connection terminals 22 on the first redistribution structure rds1. The underfill layer 24 is formed to fix and support the chip structure CS onto the first redistribution structure rds1.

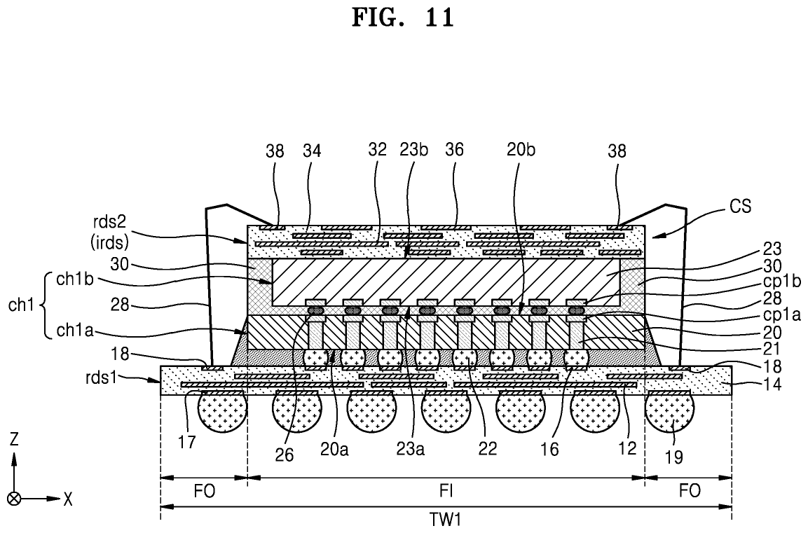

Referring to FIG. 11, the second redistribution bonding pads 38 of the second redistribution structure rds2 are electrically connected to the first redistribution bonding pads 18 of the first redistribution structure rds1 by bonding wires 28. For example, each bonding wire 28 may contact a corresponding one of the first redistribution bonding pads 18 and a corresponding one of the second redistribution bonding pads 38.

As described above, the second redistribution structure rds2 is electrically connected to the first redistribution structure rds1 by the bonding wire 28 instead of a metal pillar (or a metal post) which may be formed by an electroplating process. Accordingly, the second redistribution structure rds2 and the first redistribution structure rds1 may be electrically reliably connected to each other, e.g., by a simpler process as the electroplating process.

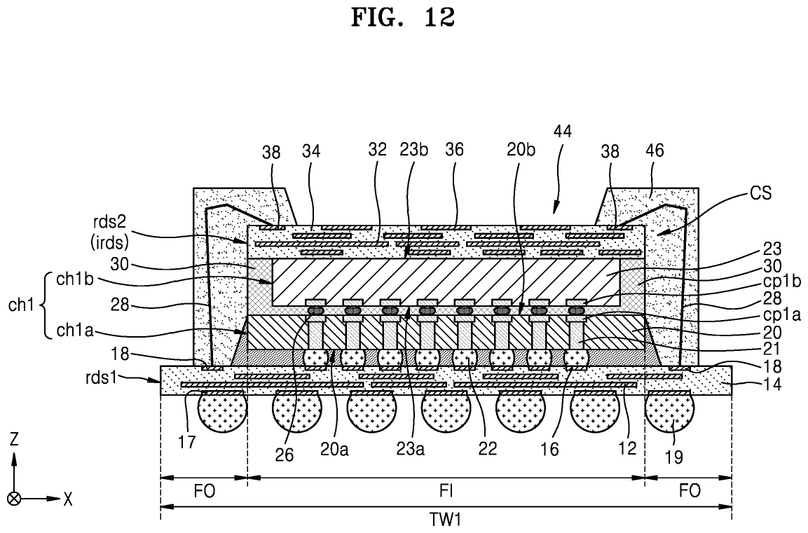

Referring to FIG. 12, on the first redistribution structure rds1, the chip structure CS is molded by the second molding layer 46, and also the second connection hole 44 is formed in the second molding layer 46 on the second redistribution structure rds2.

The second connection hole 44 may expose the third connection pads 36. In some embodiments, the second connection hole 44 may be prepared by forming the second molding layer 46 only on a portion of the second redistribution structure rds2 without performing the laser drilling process. For example, the molding material layer forming the second molding layer 46 may not be disposed on the portion in which the second connection hole 44 is formed and may be disposed on the other portion in which the second molding layer 46 is shown to be formed, thereby forming the second molding layer 46 without an additional patterning process in certain embodiments, e.g., by using a shadow mask. The semiconductor package PK2 of FIGS. 2A and 2B may be manufactured through the manufacturing processes described above.

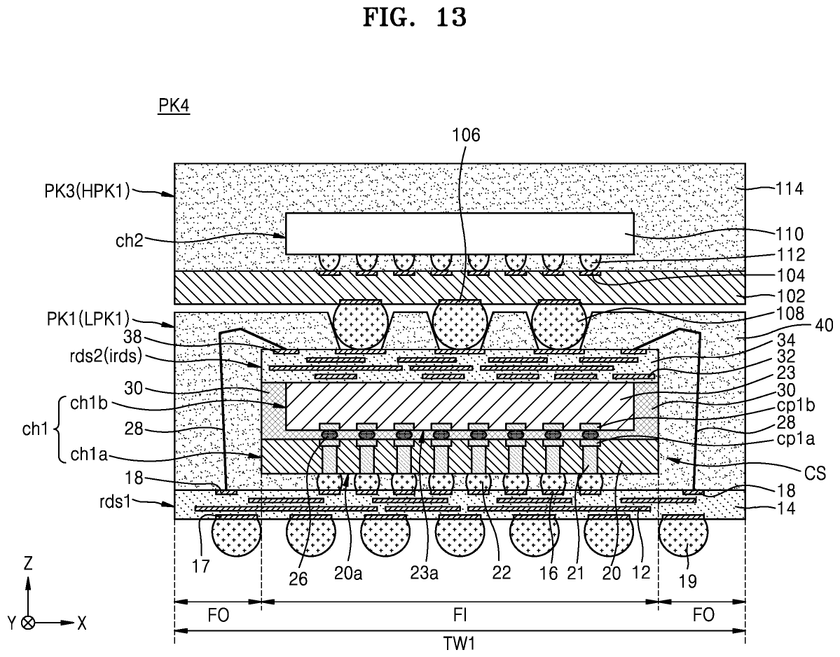

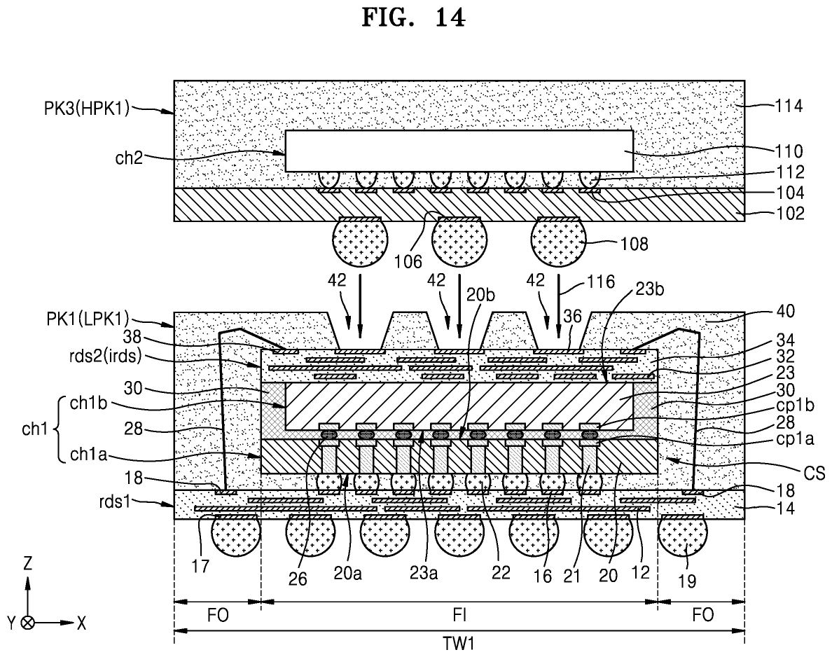

FIG. 13 is a cross-sectional view of a semiconductor package according to an embodiment, and FIG. 14 is a cross-sectional view for explaining a method of manufacturing the semiconductor package of FIG. 13.

Referring to FIG. 13, a semiconductor package PK4 may include an upper semiconductor package HPK1 mounted on a lower semiconductor package LPK1, as shown in FIG. 13. FIG. 14 shows a process of mounting the upper semiconductor package HPK1 on the lower semiconductor package LPK1. The semiconductor package PK4 may be of a package-on-package type.

The lower semiconductor package LPK1 may be the semiconductor package PK1 of FIGS. 1A and 1B. Because the lower semiconductor package LPK1 is described with reference to FIGS. 1A and 1B, the lower semiconductor package LPK1 is briefly described. The lower semiconductor package LPK1 may include the chip structure CS, the bonding wire 28, and the second molding layer 40. The chip structure CS may include a first stack semiconductor chip ch1, a second redistribution structure rds2, and a first molding layer 30. The first stack semiconductor chip ch1 may include a first sub-chip ch1a and a second sub-chip ch1b bonded to the first sub-chip ch1a.

The upper semiconductor package HPK1 may be a semiconductor package PK3. The semiconductor package PK3 may include a wiring substrate 102, a second semiconductor chip ch2, second chip connection terminals 112, an upper molding layer 114, and second external connection terminals 108.

The wiring substrate 102 may be a printed circuit board. On an upper surface and a lower surface of the wiring substrate 102, upper wiring pads 104 and lower wiring pads 106 may be arranged. The lower wiring pads 106 may be electrically connected to (e.g., may contact) the second external connection terminals 108, respectively. The second external connection terminals 108 may be electrically connected to the third connection pad 36 of the second redistribution structure rds2.

The second semiconductor chip ch2 may include a third semiconductor substrate 110. The third semiconductor substrate 110 may include or be formed of the same material as the first and second semiconductor substrates 20 and 23 of FIGS. 1A and 1B. The second semiconductor chip ch2 may be electrically connected to the wiring substrate 102 through the second chip connection terminals 112. In the present embodiment, the second semiconductor chip ch2 is connected to the wiring substrate 102 through the second chip connection terminals 112, but the second semiconductor chip ch2 may be electrically connected to the wiring substrate 102 through a bonding wire in certain embodiments.

The second semiconductor chip ch2 may be, for example, a memory semiconductor chip. The memory semiconductor chip may be a volatile memory semiconductor chip, such as Dynamic Random Access Memory (DRAM) or Static Random Access Memory (SRAM) or a non-volatile memory semiconductor chip, such as Phase-change Random Access Memory (PRAM), Magnetoresistive Random Access Memory (MRAM), Ferroelectric Random Access Memory (FeRAM), or Resistive Random Access Memory (RRAM).

As shown in FIG. 14, the semiconductor package PK4 in FIG. 13 may be manufactured by moving the second external connection terminals 108 of the upper semiconductor package HPK1 towards the third connection pads 36, which are exposed by/through the first connection holes 42 formed in the lower semiconductor package LPK1, in a direction 116 indicated by arrows. The second external connection terminals 108 of the upper semiconductor package HPK1 may be electrically connected to (e.g., may contact) the third connection pads 36 of the lower semiconductor package LPK1, e.g., by a thermal compression bonding method.

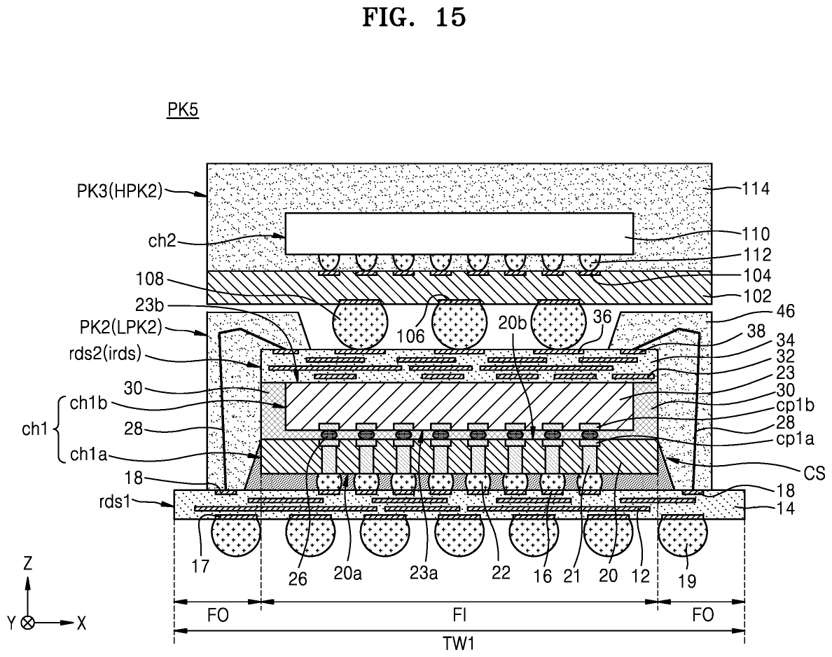

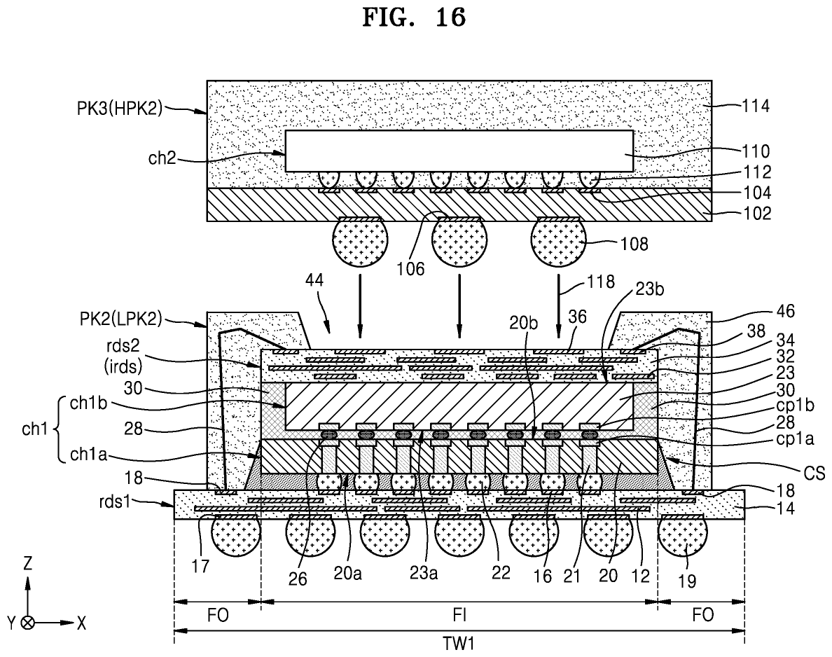

FIG. 15 is a cross-sectional view of a semiconductor package according to an embodiment, and FIG. 16 is a cross-sectional view for explaining a method of manufacturing the semiconductor package of FIG. 15.

Referring to FIG. 15, a semiconductor package PK5 may include an upper semiconductor package HPK2 mounted on a lower semiconductor package LPK2, as shown in FIG. 15. FIG. 16 shows a process of mounting the upper semiconductor package HPK2 on the lower semiconductor package LPK2. The semiconductor package PK5 may be of a package-on-package type.

The lower semiconductor package LPK2 may be the semiconductor package PK2 of FIGS. 2A and 2B. Because the lower semiconductor package LPK2 is described with reference to FIGS. 2A and 2B, the lower semiconductor package LPK2 is briefly described below. The lower semiconductor package LPK2 may include the chip structure CS, the bonding wire 28, the underfill layer 24, and the second molding layer 46. The chip structure CS may include the first stack semiconductor chip ch1, the second redistribution structure rds2, and the first molding layer 30. The first stack semiconductor chip ch1 may include the first sub-chip ch1a and the second sub-chip ch1b bonded to the first sub-chip ch1a.

The upper semiconductor package HPK2 may be the semiconductor package PK3. The semiconductor package PK3 may include the wiring substrate 102, the second semiconductor chip ch2, the second chip connection terminals 112, the upper molding layer 114, and the second external connection terminals 108. Because the semiconductor package PK3 is described above with reference to FIGS. 13 and 14, details of the semiconductor package PK3 is not described again.

On the upper surface and the lower surface of the wiring substrate 102, the upper wiring pads 104 and the lower wiring pads 106 may be arranged. The lower wiring pads 106 may be electrically connected to (e.g., may contact) the second external connection terminals 108, respectively. The second external connection terminals 108 may be electrically connected to (e.g., may contact) the third connection pads 36 of the second redistribution structure rds2.

As shown in FIG. 16, the semiconductor package PK5 in FIG. 15 may be manufactured by moving the second external connection terminals 108 of the upper semiconductor package HPK2 towards the third connection pads 36, which are exposed by/through the second connection hole 44 formed in the lower semiconductor package LPK2, in directions 118 indicated by arrows. The second connection hole 44 may expose the third connection pads 36. The second external connection terminals 108 of the upper semiconductor package HPK2 may be connected to (e.g., may contact) the third connection pads 36 of the lower semiconductor package LPK2, e.g., by a thermal compression bonding method.

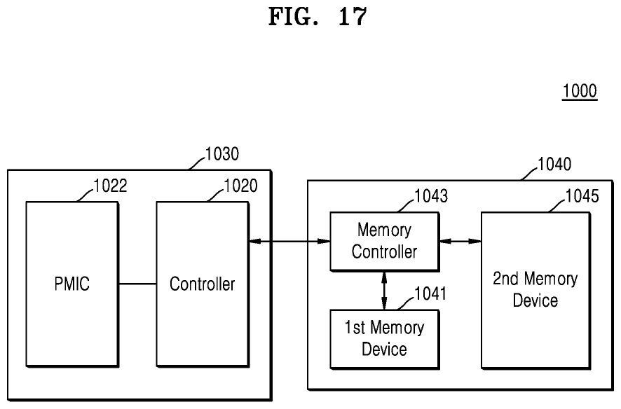

FIG. 17 is a block diagram of a structure of a semiconductor package, according to an embodiment.

Referring to FIG. 17, a semiconductor package 1000 may include any one of the semiconductor packages PK4 and PK5 according to an embodiment. The semiconductor package 1000 may include a controller chip 1020, a first memory device (or chip) 1041, a second memory device (or chip) 1045, and a memory controller 1043. The semiconductor package 1000 may further include a PMIC 1022 supplying a current of an operation voltage to each of the controller chip 1020, the first memory device 1041, the second memory device 1045, and the memory controller 1043. An operation voltage applied to each component may be identically or differently designed.

A lower semiconductor package 1030 including the controller chip 1020 and the PMIC 1022 may be the lower semiconductor packages LPK1 and/or LPK2 described above. An upper semiconductor package 1040 including the first memory device 1041, the second memory device 1045, and the memory controller 1043 may be the upper semiconductor package HPK1 or HPK2 described above.

The semiconductor package 1000 may be implemented to be included in a personal computer (PC) or a mobile device. The mobile device may be realized as a laptop, a mobile phone, a smartphone, a tablet PC, a personal digital assistant (PDA), an enterprise digital assistant (EDA), a digital still camera, a digital video camera, a portable multimedia player (PMP), a personal navigation device or a portable navigation device (PND), a handheld game console, a mobile internet device (MID), a wearable computer, an Internet of Things (IoT) device, an Internet of Everything (IoE) device, or a drone.

The controller chip 1020 may control the operation of each of the first memory device 1041, the second memory device 1045, and the memory controller 1043. For example, the controller chip 1020 may be implemented as an integrated circuit (IC), a system on chip (SoC), an AP, a mobile AP, a chip set, or a set of chips. The controller chip 1020 may include or may be a CPU, a GPU, and/or a modem. In some embodiments, the controller chip 1020 may perform functions of the modem and the AP.

The memory controller 1043 may control the second memory device 1045 according to the control of the controller chip 1020. The first memory device 1041 may be realized as a volatile memory device. The volatile memory device may be RAM, DRAM, or SRAM, but embodiments are not limited thereto. The second memory device 1045 may be realized as a storage memory device. The storage memory device may be realized as a non-volatile memory device.

The storage memory device may be realized as a flash-based memory device, but embodiments are not limited thereto. The second memory device 1045 may be realized as a NAND flash memory device. The NAND flash memory device may include a two-dimensional memory cell array or a three-dimensional memory cell array. The two-dimensional memory cell array or the three-dimensional memory cell array may include a plurality of memory cells, and in each memory cell, one-bit information or information of two or more bits may be stored.

When the second memory device 1045 is realized as a flash-based memory device, the memory controller 1043 may use (or support) a multimedia card (MMC) interface, an embedded MMC (eMMC) interface, or a universal flash storage (UFS) interface, but embodiments are not limited thereto.

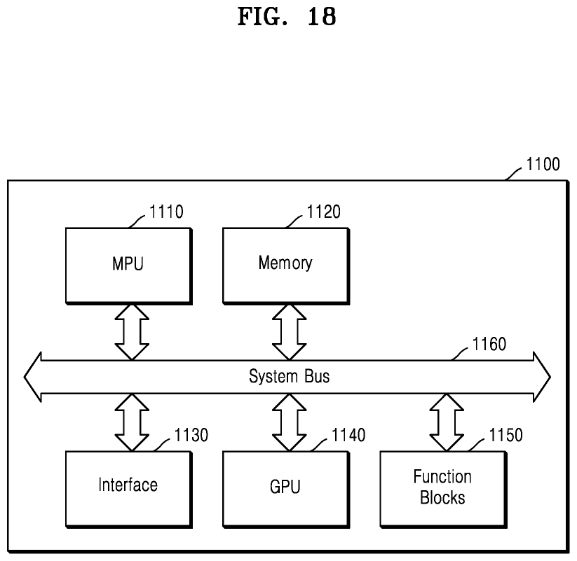

FIG. 18 is a schematic block diagram of a structure of a semiconductor package, according to an embodiment.

Referring to FIG. 18, a semiconductor package 1100 may include a microprocessor unit (MPU) 1110, a memory 1120, an interface 1130, a GPU 1140, function blocks 1150, and a system bus 1160 connecting the above-listed components to each other. The semiconductor package 1100 may include both the MPU 1110 and the GPU 1140, but may include only one of them in certain embodiments.

The MPU 1110 may include a core and an L2 cache. For example, the MPU 1110 may include a multi-core. Each one of the multi-core may have the same or different performance. Also, each of the multi-core may be activated simultaneously or in different points in time. The memory 1120 may store therein results processed by the function blocks 1150 under the control of the MPU 1110. For example, as content stored in the L2 cache of the MPU 1110 is flushed, the content may be stored in the memory 1120. The interface 1130 may perform interface with external devices. For example, the interface 1130 may perform interface with a camera, a liquid crystal display (LCD), a speaker, or the like.

The GPU 1140 may perform graphic functions. For example, the GPU 1140 may perform video codec or process three-dimensional graphics. The function blocks 1150 may perform various functions. For example, when the semiconductor package 1100 is an AP used in a mobile device, some of the function blocks 1150 may perform a communication function.

The semiconductor package 1100 may be the semiconductor packages PK4 and PK5 described above. The MPU 1110 and/or the GPU 1140 may be the lower semiconductor packages LPK1 and/or LPK2 described above. The memory 1120 may be the upper semiconductor package HPK1 or HPK2 described above. The interface 1130 and the function blocks 1150 may correspond to portions of the lower semiconductor packages LPK1 and/or LPK2 described above.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor package comprising:
a chip structure comprising a first stack semiconductor chip, which comprises a first sub-chip and a second sub-chip that is bonded to the first sub-chip and is of a different type from the first sub-chip, a first molding layer configured to mold the second sub-chip on the first sub-chip, and a first redistribution structure arranged above the first stack semiconductor chip and the first molding layer;
a second redistribution structure arranged under the chip structure and bonded to the chip structure;
a bonding wire electrically connecting the second redistribution structure to the first redistribution structure; and
a second molding layer sealing, on the second redistribution structure, the chip structure and the bonding wire.

2. The semiconductor package of claim 1, wherein the first sub-chip comprises a first sub-chip pad and a sub-through via, the second sub-chip comprises a second sub-chip pad, and the first sub-chip pad is bonded to the second sub-chip pad through an internal connection terminal.

3. The semiconductor package of claim 1, wherein the first sub-chip comprises a first sub-chip pad and a sub-through via, the second sub-chip comprises a second sub-chip pad, and the first sub-chip pad is directly bonded to the second sub-chip pad.

4. The semiconductor package of claim 1, wherein the first sub-chip comprises a first sub-chip pad and a sub-through via which are arranged on a first active surface of a first semiconductor substrate, the second sub-chip comprises a second sub-chip pad arranged on a second active surface of a second semiconductor substrate, and the first sub-chip pad and the second sub-chip pad bond between the first active surface and the second active surface.

5. The semiconductor package of claim 1, wherein the first sub-chip comprises a first lower sub-chip and a second lower sub-chip which are spaced apart from each other in a horizontal direction, the first lower sub-chip comprises a first lower sub-chip pad and a sub-through via, the second lower sub-chip comprises a second lower sub-chip pad, the second sub-chip comprises second sub-chip pads, and the first lower sub-chip pad and the second lower sub-chip pad are directly bonded to the second sub-chip pads respectively.

6. The semiconductor package of claim 1, wherein the first redistribution structure comprises a first redistribution layer and a first redistribution bonding pad electrically connected to the first redistribution layer,
the second redistribution structure comprises a second redistribution layer and a second redistribution bonding pad electrically connected to the second redistribution layer, and
the bonding wire electrically connects the second redistribution bonding pad to the first redistribution bonding pad.

7. The semiconductor package of claim 1, wherein the first molding layer is arranged on sidewalls of the second sub-chip and between the first sub-chip and the second sub-chip.

8. The semiconductor package of claim 1, wherein, on the second redistribution structure, the second molding layer is arranged on sidewalls of the first stack semiconductor chip, sidewalls of the first molding layer, and a top and side surfaces of the first redistribution structure.

9. The semiconductor package of claim 1, wherein the first redistribution structure is arranged on an upper surface of the first molding layer and an upper surface of the second sub-chip.

10. The semiconductor package of claim 1, wherein a first chip connection terminal is further arranged under the first sub-chip, the first chip connection terminal being connected to the second redistribution structure, and
an underfill layer supporting the first chip connection terminal is further arranged under the first sub-chip.

11. A semiconductor package comprising:
a first redistribution structure comprising a fan-in region and fan-out regions, which surround the fan-in region, the first redistribution structure further comprising first redistribution bonding pads arranged in the fan-out regions;
a chip structure arranged on the first redistribution structure in the fan-in region, wherein the chip structure comprises: a first stack semiconductor chip comprising a first sub-chip and a second sub-chip that is of a different type from the first sub-chip and is bonded to the first sub-chip; a first molding layer sealing the second sub-chip on the first sub-chip; and a second redistribution structure arranged on the first stack semiconductor chip and the first molding layer, the second redistribution structure comprising a second redistribution bonding pad in the fan-in region;
a bonding wire electrically connecting the second redistribution bonding pad in the fan-in region to a first redistribution bonding pad in one of the fan-out regions; and
a second molding layer molding the chip structure and the bonding wire on the first redistribution structure in the fan-in region and the fan-out regions.

12. The semiconductor package of claim 11, wherein the first redistribution bonding pad is arranged on a top surface the first redistribution structure, and the second redistribution bonding pad is arranged on a top surface of the second redistribution structure.

13. The semiconductor package of claim 11, wherein the first molding layer contacts side surfaces of the second sub-chip in the fan-in region, and the second molding layer contacts sidewalls of the first sub-chip, sidewalls of the first molding layer, and sidewalls of the second redistribution structure above the first redistribution structure in the fan-in region and the fan-out regions.

14. The semiconductor package of claim 11, wherein a first chip connection terminal connected to the first redistribution structure is further arranged under the first sub-chip in the fan-in region, and an underfill layer supporting the first chip connection terminal is further arranged under the first sub-chip.

15. The semiconductor package of claim 11, wherein the first sub-chip comprises a first sub-chip pad and a sub-through via, the second sub-chip comprises a second sub-chip pad, and the first sub-chip pad and the second sub-chip pad are bonded to each other by an internal connection terminal or directly bonded to each other.

16. A semiconductor package comprising:
a first redistribution structure comprising a fan-in region and fan-out regions, which are located on opposite sides of the fan-in region, the first redistribution structure further comprising a first redistribution bonding pad in the fan-out regions;
a chip structure arranged on the first redistribution structure in the fan-in region, the chip structure comprising a first stack semiconductor chip including a first sub-chip and a second sub-chip that is of a different type from the first sub-chip and is bonded to the first sub-chip by an internal connection terminal, a first molding layer sealing the second sub-chip on the first sub-chip, and a second redistribution structure arranged above the first stack semiconductor chip and the first molding layer, the second redistribution structure comprising a second redistribution bonding pad in the fan-in region;
a bonding wire electrically connecting the second redistribution bonding pad in the fan-in region to the first redistribution bonding pad in the fan-out regions; and
a second molding layer molding the chip structure and the bonding wire above the first redistribution structure in the fan-in region and the fan-out regions,
wherein the first sub-chip comprises a first sub-chip pad and a sub-through via, the second sub-chip comprises a second sub-chip pad, the first sub-chip pad is bonded to the second sub-chip pad by the internal connection terminal, and second widths of the second redistribution structure and the first sub-chip are less than a first width of the first redistribution structure.

17. The semiconductor package of claim 16, wherein a first connection pad and a second connection pad are further arranged on and under the first redistribution structure respectively, a first chip connection terminal is further connected to the first connection pad, and a first external connection terminal is further connected to the second connection pad.

18. The semiconductor package of claim 16, wherein the second redistribution structure is arranged on an upper surface of the first molding layer and an upper surface of the second sub-chip, a third connection pad is further arranged above the second redistribution structure, and a connection hole exposing the third connection pad is further arranged in the second molding layer.

19. The semiconductor package of claim 18, further comprising an upper semiconductor package connected to the third connection pad above the second redistribution structure and the second molding layer,
wherein the upper semiconductor package comprises a wiring substrate, a second semiconductor chip mounted on the wiring substrate, an upper molding layer molding the second semiconductor chip on the wiring substrate, and a second external connection terminal attached under the wiring substrate, and
the second external connection terminal is arranged in the connection hole and is electrically connected to the third connection pad.

20. The semiconductor package of claim 19, wherein the first stack semiconductor chip comprises any one of a controller chip and a power management integrated circuit, and the second semiconductor chip comprises a memory chip.
